(19) United States
(12) Patent Application Publication
(10) Pub. No.: US 2026/0202239 A1
(43) Pub. Date: Jul. 16, 2026

(54) Infrasound Sensors for Large Arrays

(71) Applicant: TDA Research, Inc, Golden, CO (US)

(72) Inventors: David P. Eisenberg, Denver, CO (US); Nathan Weinstein, Montrose, CO (US); Brant Beck, Littleton, CO (US); Cory Van Beek, Arvada, CO (US); Grant Bracht, Denver, CO (US)

(21) Appl. No.: 19/036,955

(22) Filed: Jan. 24, 2025

Related U.S. Application Data
(60) Provisional application No. 63/624,681, filed on Jan. 24, 2024.

(51) Int. Cl. G01H 3/06; G01D 11/24; G21J 5/00; H05K 1/181; H05K 7/14

(52) U.S. Cl. CPC G01H 3/06; G01D 11/245; H05K 1/181; H05K 7/1427; G21J 5/00; H05K 2201/10098; H05K 2201/10151

(57) ABSTRACT

A low-cost infrasound sensor comprising a main body, a pressure port with a sensing element, a printed circuit board, a transmitter, and a means for elevating the main body above the ground such that when the infrasound sensor is placed upright, the sensing element is located at most 1 centimeter above the ground surface. Also, an array of said low-cost infrasound sensors. A method of using said infrasound sensor, comprising measuring the pressure at most 1 centimeter above the ground surface. Optionally, using a differential GPS unit and a differential GPS sensor along with scannable labels to create a deployment map of an array of said infrasound sensors. Optionally, using low-cost oscillators in the infrasound sensors and a single GPS clock to synchronize the low-cost oscillators. Optionally, using a hierarchal data structure with varying nodes to save power while transmitting data from the infrasound sensors to a central computer.

### RELATED APPLICATIONS

The present application claims the benefit of provisional application no. 63/624,681 filed Jan. 1, 2024 (by David Eisenberg, Nathan Weinstein, Brant Beck, Cory Van Beek, and Grant Bracht, attorney docket number 24-1), which is incorporated by reference herein.

### STATEMENT OF GOVERNMENT INTEREST

This invention was made in part using U.S. government funding under contract #HDTRA2-19-C-0003 awarded by the Defense Threat Reduction Agency (DTRA). The government has certain rights in this invention.

### BACKGROUND

The study of infrasound propagation has become increasingly prominent due to the Comprehensive Nuclear-Test-Ban Treaty (CTBT), which opened for signature in 1996, which bans any nuclear weapon test explosion for any purpose. Infrasound testing sites are crucial in verifying the treaty, as they serve to detect the existence and location of nuclear explosions, whether they be atmospheric or in-ground, from large distances from the source. This detection system provides a safe-guard against potential nuclear warfare. Other explosions, such as mining explosions and surface explosions, can be identified via infrasound sensors as well, and ensures safety in such situations. Infrasound studies can also give insight to disruptions such as earthquakes, volcanoes, and avalanches. Infrasound is capable of measuring and analyzing natural signals from large phenomena at further distances than audible noise, because infrasound travels further without dissipating.

Infrasound sensors (i.e. microbarographs) measure low frequency acoustic signals (infrasound is generally considered to be any acoustic signal with a frequency below 20 Hz, the lower limit of human hearing). In short, a microbarograph is a differential pressure sensor where one of the ports is open to the atmosphere and the other is connected to a reference volume with a slow leak to the environment. The reference volume allows the pressure sensor to detect changes in the atmospheric pressure while the slow leak acts as a high pass filter. Since barometric pressure changes naturally over the course of the day, the slow leak filters out these natural, extremely low frequency pressure variations (changes in air pressure due to weather systems or temperature), and just leaves the higher frequency pressure signals.

Generally, acoustic sensors are used in low number, as point sensors. They can detect a signal, but are not capable of determining the shape of that signal in space at a given time, or how that signal propagates through space over time (over short distances). When an array of infrasound sensors are used to detect signals in a larger physical area, a generally small number of sensors are typically spaced further from one another to accommodate the area, leading to low degrees of spatial correlation and improper monitoring. This is largely because current acoustic microbarograph sensors are expensive, and it is economically infeasible to produce large number of densely spaced acoustic arrays which can detect various natural and manmade phenomena. The cheapest sensor on the market is the Raspberry Pi Shake and Boom, which only works up to 50 Hz and costs ~$1000 to purchase. After that, commercial sensors are sold by companies like Hyperion and Chapparal, whose sensors typically cost ~$5000 to purchase. Many sensors, such as those taught in U.S. Pat. No. 67,881,417B1 and CN209044067U, rely on more expensive fiber optic pressure sensor technologies, and US20110098950A1 teaches away from using simpler microbarograph technologies in infrasound sensors due to their inherent bulkiness.

Although infrasound waves can travel vast distances, even around the world, they are susceptible to wind and temperature variations. At distances of hundreds of miles, the infrasound wave may be less affected by obstacles in its path, but the infrasound sensor becomes a problem in itself. Even small gusts of wind, weather changes, and other natural atmospheric variances cause infrasound sensors to pick up extra noise which makes infrasound signals extremely difficult or impossible to decipher from the noise. Filtering out wind noise is a huge issue in the infrasound community. One approach to wind noise filtering is the “Quad-Disc” static pressure probe from Nishiyama and Bedard (1991). U.S. Pat. No. 8,671,763B2 teaches a windscreen to limit wind noise when measuring outdoor infrasonic sound. Limitations of this teaching, however, are the lack of mobility once sensors have been deployed and the necessity of proximity to a control station which limits the number of sensors which can be deployed. U.S. Pat. No. 4,838,087A teaches another approach to wind noise filtering. US20110098950A1 and U.S. Pat. No. 7,269,537B1 teach infrasound sensors using multiple pressure and/or disturbance sensors to accomplish wind noise filtering by internally or externally comparing and transforming data from each sensor and canceling out unwanted signals. Each of these methods to wind noise filtering includes more than one sensor communicating with other sensors or a central data processor to accomplish their goal, increasing complexity and manufacturing cost of the respective sensors, and inhibiting deployment in very large quantities.

Sound source localization is done by multiple techniques, and generally compares the arrival time of sound waves to sensors of differing locations to determine the direction of the source. More sensors create a more accurate picture of sound shape, size, movement, and source. U.S. Pat. No. 9,800,973 teaches one of such techniques. Accuracy and precision of any data measurement increases as more data points are collected. Because of the inability to deploy many sensors, there is currently an imprecise understanding of infrasound propagation, hindering researchers in real time, accurate tracking of nuclear testing, seismic movement, natural disasters, and other explosive and infrasound-inducing events.

Currently, there lacks an infrasound sensor which is easily manufactured and accounts for wind noise correction without additional technologies or costs required. There are limitations on the amount of infrasound sensors that can be deployed of the current types available due to at least one of the following reasons: (i) expenses to manufacture or buy many sensors, the expenses due to complex technologies, multiple sensors, or expensive wind filters present in the sensors; (ii) proximity requirements for use of multiple sensors in relation to a central computer due to wired connections; (iii) semi-permanent installation of sensors; and, (iv) size, weight, or shape of the sensors.

For the foregoing reasons, there is a need for a re-designed acoustic microbarograph sensor which is made from less expensive materials and/or uses less complex sensing techniques, without sacrificing detection accuracies, to allow for the deployments of a large array of sensors. It should correct for wind noise without incurring additional costs or using complex outside-source software. This is necessary to improve data gathering on nuclear testing, explosions, earthquakes, avalanches, and other sources of natural disaster and infrasound waves.

### SUMMARY OF THE INVENTION

The disclosed relates to infrasound sensors and solves the limitations of the prior art. The apparatus is a low-cost infrasound sensor, which can be used in a large array due to its inexpensive manufacture to improve data collection of infrasound movement and shape over short distances, while maintaining highly accurate sound readings, GPS coordinates of deployment, and synchronized data uploads. A feature of this sensor is that it relies on a simple method of sampling pressure very close to the ground to reduce wind noise without requiring an expensive wind filter. Another feature of this sensor is that it uses its own sensor body volume as the backing volume for the microbarograph, resulting in decreased complexity of the sensor mechanics. A feature of using the sensor in an array is that it transfers data in a hierarchical structure, which minimizes power consumption by turning off power-hungry processes for most of the time of use. Another feature of using the sensor in an array is that a user can deploy hundreds of sensors and they will remain synced to provide an accurate geographical picture of infrasound waves. This sensor employs a simplistic measuring technique close to the ground which eliminates the need for additional sensors or filters to account for atmospheric noise. A version of the infrasound sensor is shown in FIG. 1.

The present infrasound sensors offer a few huge benefits compared to what is currently available. First, they are cheap. Typically, getting a single infrasound sensor on the market costs $1,000 and could be as much as $10,000. The present sensors will cost $100s, so it is much cheaper to use in large arrays. The present sensors also provide a wider frequency range than the $1000 sensors. The present sensors will be ideal for any application where sensors could be lost, damaged, or abandoned. They will also provide a huge benefit for studies that have limited budgets to spend on sensors.

Embodiments of the present infrasound sensor provide advantages over the current state-of-the-art, including but not limited to: using the sensor's body as the backing volume for the microbarograph; using hall effect sensors as switches to maintain air-tightness; placing the sample port very close to the ground to reduce wind noise; using a single GPS clock and an RF transmitter to keep all sensors in sync without using expensive clocks in each sensor; hierarchal data structure to save power (central computer communicates with medium nodes via Wi-Fi and medium nodes communicate with low nodes via BLE®); generating accurate sensor location maps using QR codes® or other scannable labels with unique identified for each sensor along with a scanner that wirelessly communicates with a GPS “hat”, using cheaper materials and methods for generating an accurate deployment map of a large array (greater than 100 units) of infrasound sensors.

The present disclosure provides an infrasound sensor, specifically a low-cost infrasound sensor, comprising: a) a main body, having a bottom side and a top side; b) a pressure port extending from the bottom side of the main body, having a proximal end connected to the main body and a distal end open to an outside air, further comprising a pressure sensor inside the main body or the pressure port, wherein the pressure sensor can measure an outside air pressure; and, c) at least 1 leg extending from the main body; wherein, when the infrasound sensor is installed on a ground surface with the bottom side facing the ground surface, the distal end of the pressure port is more than 0 centimeters and at most 1 centimeter above the ground surface. In an embodiment, the pressure sensor further comprises an orifice for a small leak, wherein the main body is a backing volume for the small leak. In an embodiment, the main body acts as a backing volume for a slow leak in the main body of the infrasound sensor. Optionally, the backing volume equilibrates an inside pressure to an outside pressure in less than 5 seconds. In an embodiment the backing volume equilibrates the inside pressure to the outside pressure in about 3 seconds.

The infrasound sensor may further comprise a) a printed circuit board (PCB) on the inside of the main body; and, b) a transmitter attached to the PCB, wherein the transmitter can communicate data from the pressure sensor to an external computer.

In an embodiment, the infrasound sensor further comprises at least 1 hall effect sensor on the inside of the main body, or attached to the PCB, wherein the at least 1 hall effect sensor is operable to turning the infrasound sensor on and off with a magnet. The hall effect sensors allow for the infrasound sensor to be operated without disrupting the airtightness of the device, which is critical for measuring pressure with the slow leak.

Optionally, the infrasound sensor further comprises a low-cost oscillator, such as a low-cost clock, attached to the PCB. The low-cost oscillator may have an accuracy of at least 10 ppm. Optionally, the infrasound sensor further comprises a solar panel on the top side of the main body.

In a preferred embodiment, the at least 1 leg extending from the main body is 3 legs or at least 3 legs. Optionally, each of the 3 legs or at least 3 legs further comprises a stabilizing means. In an optional embodiment, the stabilizing means comprises a foot attached to each of the at least 3 legs. Each foot may further comprise either: a hole in the center thereof, wherein the hole provides a space to insert a stake or a pole, or; a post, wherein the post extends to dig into the ground surface.

Preferably, the infrasound sensor has a frequency detection range of 0.1 Hz-100 Hz.

The present disclosure also provides an array of infrasound sensors, or an array of low-cost infrasound sensors, comprising a multiplicity of infrasound sensors, wherein each infrasound sensor comprises: a) a main body, having a bottom side and a top side; b) a pressure port extending from the bottom side of the main body, having a proximal end connected to the main body and a distal end open to an outside air, further comprising a pressure sensor inside the main body or the pressure port, wherein the pressure sensor can measure an outside air pressure; and, c) at least 1 leg extending from the main body; wherein, when the infrasound sensor is installed on a ground surface with the bottom side facing the ground surface, the distal end of the pressure port is more than 0 centimeters and at most 1 centimeter above the ground surface. The array of infrasound sensors may comprise at least 50 sensors, at least 100 sensors, or at least 200 sensors.

The array of infrasound sensors may further comprise: a scannable label on the outside of each infrasound sensor, wherein the scannable label is capable of data storage and communication, and wherein the scannable label has a design based on a MAC address of the infrasound sensor; a differential GPS unit; and a differential GPS sensor, wherein the differential GPS sensor is capable of scanning the scannable label and communicating with the differential GPS unit.

The present disclosure also provides a method of using an infrasound sensor comprising the steps: a) providing an infrasound sensor comprising: i) a main body, having a bottom side, a top side, an inside, and an outside; ii) a pressure port extending from the bottom side of the main body, having a proximal end connected to the main body and a distal end open to an outside air, further comprising a pressure sensor having a sensing element inside the main body or the pressure port, wherein the pressure sensor can measure an outside air pressure; iii) at least 1 leg extending from the main body; b) placing the infrasound sensor on a ground surface; and, c) measuring the pressure.

In an embodiment of the method of using an infrasound sensor, measuring the pressure comprises the steps: d) continuously measuring a temperature of the sensing element; e) determining an air flow rate and a pressure differential between the outside and the inside of the infrasound sensor based on the temperature of the sensing element; f) equilibrating the pressure differential such that infrasound signals can be resolved, wherein the infrasound signals have a period of up to 10 seconds.

In another embodiment of the method of using an infrasound, the infrasound sensor further comprises a scannable label, wherein the scannable label is capable of data storage and communication, and wherein the scannable label has a unique identifying number, further comprising the steps: providing a differential GPS unit and a differential GPS sensor, wherein the differential GPS sensor is capable of scanning the scannable label and communicating with the differential GPS unit; scanning the scannable label with the differential GPS sensor; placing the differential GPS unit on the top side of the main body of the infrasound sensor; and, saving the unique identifying number and its GPS coordinates in a CSV file. Preferably, the differential GPS unit is accurate within 1 centimeter. Optionally, the method further comprises the step: creating a deployment map from the CSV file.

Optionally, the method further comprises using at least one hall effect sensor to turn the infrasound sensor on and off, wherein the at least one hall effect sensor is on the inside of the main body of the infrasound sensor and a magnet can activate the at least one hall effect sensor from the outside of the main body of the infrasound sensor, and wherein the method does not comprise opening the main body of the infrasound sensor. The at least one hall effect sensor may be attached to a PCB inside the main body of the infrasound sensor.

The disclosure also provides a method of using an array of infrasound sensors comprising the steps: a) providing a multiplicity of infrasound sensors, wherein each infrasound sensor comprises: i) a main body, having a bottom side, a top side, an inside, and an outside; ii) a pressure port extending from the bottom side of the main body, having a proximal end connected to the main body and a distal end open to an outside air, further comprising a pressure sensor inside the main body or the pressure port, wherein the pressure sensor can measure an outside air pressure; iii) at least 1 leg extending from the main body; wherein, when the infrasound sensor is installed on a ground surface with the bottom side facing the ground surface, the distal end of the pressure port is more than 0 centimeters and at most 1 centimeter above the ground surface; b) placing the multiplicity of infrasound sensors on the ground surface; and, c) measuring the pressure at each infrasound sensor. Optionally, the multiplicity of infrasound sensors comprises at least 100 infrasound sensors. The multiplicity of infrasound sensors may also comprise at least 150 infrasound sensors, or at least 200 infrasound sensors.

In an embodiment of the method of using an array of infrasound sensors, each infrasound sensor further comprises a printed circuit board (PBC) further comprising an oscillator having a less accurate time attached to the PCB, wherein the less accurate time is at least 50% less accurate than a GPS clock, and further comprising the steps: d) providing a GPS clock having a more accurate time; and, e) emitting an RF signal from the GPS clock to the simple oscillator on the inside of the main body of each infrasound sensor, wherein the RF signal resets the less accurate time to match the more accurate time. The RF signal may be a 915 MHz RF signal. The RF signal may be emitted once every 10 seconds, 30 seconds, 1 minute, or 100 seconds. Preferably, the RF signal is detectable for at least 1000 feet.

In another embodiment, the method of using an array of infrasound sensors further comprises the steps: d) creating a deployment map of the multiplicity of infrasound sensors; and, e) continuously updating the deployment map with the data at each infrasound sensor. Preferably, the method further comprises locating a source of an infrasound signal. Optionally, each infrasound sensor further comprises a scannable label, wherein the scannable label is capable of data storage and communication, wherein the scannable label has a unique identifying number, and creating a deployment map of the multiplicity of infrasound sensors comprises the steps: i) providing a differential GPS unit and a differential GPS sensor, wherein the differential GPS sensor is capable of scanning the scannable label and communicating with the differential GPS unit; ii) scanning the scannable label of an infrasound sensor with the differential GPS sensor; iii) placing the differential GPS unit on top of the main body of the infrasound sensor; iv) saving the unique identifying number and its GPS coordinates in a CSV file; v) repeating steps ii)-iv) for each infrasound sensor; and, vi) generating a deployment map from the CSV file. Preferably, the method further comprises locating and identifying a source of an infrasound signal.

In another embodiment, the method of using an array of infrasound sensors further comprises the step: d) combining at least one datum from each infrasound sensor at the external computer. Combining at least one datum from each infrasound sensor at the external computer may comprise the steps: i) providing a series of low nodes and a series of medium nodes on a wireless network, wherein each medium node has a maximum data capacity; connecting the external computer to the series of medium nodes on the wireless network, wherein the wireless network is kept in a sleep mode unless data is being transmitted from the series of medium nodes to the external computer or from the series of low nodes to the external computer; iii) connecting each medium node to at most 4 low nodes on a wireless personal area network, wherein the wireless personal area network is kept in a sleep mode unless data is being transmitted to the medium nodes; iv) collecting data from the infrasound sensor in the series of low nodes and the series of medium nodes; v) turning on the wireless personal area network after every 5 seconds of collecting data to transmit data from the series of low nodes to the series of medium nodes; vi) turning on the wireless network when a medium node reaches its maximum data capacity to transmit data from the medium node to the external computer. Preferably, each infrasound sensor further comprises a solar panel on the top side of the main body of the infrasound sensor. In an embodiment, the solar panel recharges the infrasound sensors, the series of low nodes, and the series of medium nodes such that the infrasound sensor is operable for at least 7 days without requiring an external charging source.

### BRIEF DESCRIPTION OF FIGURES

FIG. 1: Infrasound sensor.

FIG. 2: Mechanism for detecting infrasound using infrasound sensor.

FIG. 3: Inside of the main body of the infrasound sensor.

FIG. 4A: A top view of a printed circuit board.

FIG. 4B: A bottom view of a printed circuit board.

FIG. 5: Mechanism for detecting infrasound using infrasound sensor and establishing GPS-accurate array.

FIG. 6: Hierarchal data structure.

FIG. 7: Data flow in hierarchal data structure.

FIG. 8A: Spectrogram from a single sensor at Kirkland Air Force Base present infrasound sensor with labels designating the signal.

FIG. 8B: Clean spectrogram from a single sensor at Kirkland Air Force base present infrasound sensor.

FIG. 8C: Spectrogram from a single sensor at Kirkland Air Force base comparable infrasound sensor in the art.

FIG. 9A: Spectrogram from a single sensor at Kirkland Air Force Base present infrasound sensor.

FIG. 9B: Spectrogram from a single sensor at Kirkland Air Force Base comparable infrasound sensor in the art.

### DETAILED DESCRIPTION OF THE INVENTION

In the summary of the invention above and in the Detailed Description of the Invention, and by the claims below, and in the accompanying drawings, reference is made to particular features of the invention. It is to be understood that the disclosure of the invention in this specification includes all possible combinations of such particular features. For example, where a particular feature is disclosed in the context of a particular aspect or embodiment of the invention, or a particular claim, that feature can also be used, to the extent possible, in combination with and/or in the context of other particular aspects and embodiments of the invention, and in the invention generally.

The term “comprises” and grammatical equivalents thereof are used herein to mean that other components, ingredients, steps, etc. are optionally present. For example, an article “comprising” (or “which comprises”) component A, B, and C can consist of (i.e. contain only) components A, B, and C, or can contain not only components A, B, and C but also one or more other components.

The term “at least” followed by a number is used herein to denote the start of a range beginning with that number (which may be a range having an upper limit or no upper limit, depending on the variable being defined). For example, “at least 1” means 1 or more than 1. The term “at most” followed by a number is used herein to denote the end of a range ending with that number (which may be a range having 1 or 0 as its lower limit, or a range having no lower limit, depending on the variable being defined). For example, “at most 4” means 4 or less than 4, and “at most 40%” means 40% or less than 40%. When, this this specification, a range is given as “(a first number) to (a second number)” or “(a first number)-(a second number)”, this means a range whose lower limit is the first number and whose upper limit is the second number. For example, “2 to 10 millimeters” means a range whose lower limit is 2 mm, and whose upper limit is 10 mm.

The term “main body” means an airtight encasement for the apparatus'internal components, including electronics, a backing volume of air, and structural. It may be separable, such as into a top and bottom half, however the parts must come together to be fully sealed with an O-ring or an equivalent thereof.

The term “pressure port” means an opening connected to the outside atmosphere, where the opening can hold a pressure sensor and connects back to the body of the infrasound sensor. The pressure port may be a tube that extends from the main body to a desired position to sense pressure changes. It may be made of a hard plastic, or other rigid material. The pressure port allows for fluid communication between the outside air in the environment and the pressure sensor.

The term “sensing element” means a component which is capable of measuring pressure by initially sensing an air flow, or an equivalent thereof, and inferring the pressure difference from this data point. The sensing element may be a mass flow sensor, thermal flow sensor, or the like.

The term “printed circuit board” means a single medium to connect all the electrical components of the apparatus to one another in a circuit, providing channels and pathways for electricity and signals to follow. The printed circuit board (PCB) is comprised of conductive and insulating layers, where the electrical components may be fixed to conductive areas of the PCB, and pathways may be traced with copper in specific widths, thicknesses, and lengths to carry each source of power or signal. The PCB may have any variety of layouts of its etched pathways, so long as it maintains functionality and cohesion of each of the apparatus'electrical components. It may be single-sided, double-sided, or multi-layer. PCBs are used in nearly all electronic products, and their use and manufacture is known to those of ordinary skill in the art.

The term “transmitter” means an electronic device which can accept signals from the device which it is attached to and send this data to a receiver across a medium. The data may be sent via electromagnetic waves.

The term “leg” means a physical extension from the main body of the apparatus to the ground, providing stabilization and holding the apparatus above the ground. The leg may be made of a variety of materials, including plastic, metal, wood, and the like. The leg may be permanently attached to the sensor body, or detachable for easy storage. The leg may be attached in any configuration such that the pressure sensor is not disturbed, extra wind noise does not result from its placement, and the main body of the sensor is stable. The entire apparatus is supported and does not lend itself to movement when subjected to disturbances such as wind, weather, noise, or equivalents. At least 1 leg is required, and in a preferable embodiment, 3 legs are used.

The term “proximal end” means the end of the pressure port that is closer (attached) to the main body of the infrasound sensor.

The term “distal end” means the end of the pressure port that is further (not attached, open to the environment) from the main body of the infrasound sensor.

The term “backing volume” means a finite and stable volume of air which is connected to the outside atmosphere only by means of a slow leak. This serves as a reference to natural changes in barometric pressure, as the pressure within the backing volume will change at a very slow rate and not due to higher frequency signals that the outside sensing element may pick up.

The term “equalizing leak” or “small leak” or “slow leak” means a change in internal pressure within the backing volume which acts as a high pass filter to remove very slow noise, such as barometric pressure changes. In the present apparatus, the slow leak occurs through the sensing element itself, as heat is removed and pressure in the microbarograph can be inferred. With a system volume of 1.8 L, and a time constant of ~3 seconds, the small leak rate ~4.3e⁻⁹ m³/s-Pa. This means that for each pascal of pressure difference between the inside and outside, the flow rate increases by 4.3e⁻⁹ m³/s or 4.3 mm³/s. Changing the leak rate affects the accuracy of the sensor.

The term “equilibrates” as used in the claims means that the pressure moves from its maximum difference to 63.2% (1-1/e) of the way toward equilibrium. The equilibration rate is based on the system's time constant. A preferred system has a time constant of ~3 s (due to the 1.8 L backing volume and the leak rate through the pressure sensor). This means that in 3 s, the pressure will move from its maximum difference to 63.2% (1-1/e) of the way toward equilibrium.

The term “hall effect sensor” means a component which is capable of sensing the production of a potential difference across an electrical conductor that is transverse to an electrical current in the conductor and to an applied magnetic field perpendicular to the current, known as the Hall voltage. The term “Hall effect” is named after Edwin Hall who observed the nature of current charges when a magnetic field is applied to the perpendicular environment, and his work is described in “The discovery of the Hall effect” (Phys Educ. Vol 14, 1979).

The term “handheld magnet” means an object that can be brought toward and away from the infrasound sensor which produces a magnetic field.

The term “oscillator” or “simple oscillator” means a mechanical or electronic device which produces a periodic, oscillating, or alternating signal that regulates time and does not include advanced time-keeping or regulating technologies. Nonlimiting examples of simple oscillators are crystal oscillators, quartz oscillators, harmonic oscillators, digital clocks, mechanical clocks, battery-powered clocks, and equivalents. A simple oscillator is cheaper and less advanced than a more accurate, expensive oscillator (like a GPS clock). A simple oscillator may have an accuracy of 10 ppm or greater (where greater means >10 ppm, for example 20 ppm).

The term “stabilizing means” means additional elements which prevent the apparatus from falling, breaking, moving, shifting, collapsing, and the like. Stabilizing means can include feet attached to the apparatus'legs, where the feet may have one or more posts, spikes, poles, or equivalents extending into the ground; or feet with holes for a user to introduce their own stakes, poles, screws, or equivalents through the holes and into the ground; or methods of attaching legs to semi-permanent qualities of the ground such as blocks of cement or the like with appropriate points for attachment or partial burial in the ground.

The term “solar panel” means a device which can collect sunlight and convert it into electric current by using photovoltaic cells or mirrors that concentrate solar radiation, which in turn powers the device without the need for an energy-consuming power source.

The term “frequency range” means the interval of sound frequencies the apparatus is capable of detecting and producing decipherable signals for. Sound below 20 Hz is considered infrasound, and inclusion of these lower values qualifies the sensor as an infrasound sensor.

The term “differential GPS unit” means a supplemented and enhanced version of traditional global navigation satellite systems, which are commonly known to people having ordinary skill in the art, correcting for random satellite timing errors established by the United States Department of Defense. Accuracy is increased as a reference station containing a very accurate clock has a known exact location. Signals from a mobile GPS receiver (which is the part of the unit which is placed on top of the infrasound sensors to exactly locate them with coordinates) are decoded and corrected by the reference GPS due to its extreme accuracy and based on the premise that two receivers that are relatively close together will experience similar atmospheric errors.

The term “scannable sticker” means a label that is easy to adhere and later remove to an object which can be scanned like a barcode and communicate data for a machine to read. The label may be a QR code®, or an equivalent label with data storage and communication capabilities.

The term “design” in the claims means the appearance of the scannable sticker which is associated with the data stored in the sticker. The design of each sticker is unique to the sensor it is associated with, and the design is what determines the data that will be communicated through scanning the sticker.

The term “MAC address” means “media access control address” and is a 12-digit hexadecimal number assigned to each device connected to a network, that network may be Wi-Fi, so each infrasound sensor within an array of sensors has its own unique identifying address.

The term “CSV file” means a text file format that stores tabular data, with each line of the file representing one data record. Each data record consists of the GPS coordinates and unique identifying number of an individual sensor in a deployment field, allowing an external computer to read the file and create an accurate deployment map from the data records.

The term “air flow rate” means the measurement of amount of air per unit of time that flows through a particular device.

The term “deployment map” means a two-dimensional depiction of active sensors within an array, with their relative locations are accurate and a user can interact with and identify individual sensors on the map. It may be a simple GPS-coordinate-based map with identifying symbols, such as dots, icons, letters, etc., representing individual sensors within the network. The map may include more topographic features, and may be interactive.

The term “resolved” means that the signal is not filtered out by the slow leak, nor is it difficult to see or extract from noise. The infrasound sensors described herein can detect signals that are visible without requiring external noise-correction software or complex shielding technologies.

The term “GPS clock” means a time-keeping device which uses a constellation or orbiting satellites to provide internationally accurate time.

The term “RF signal” means a radio frequency signal which uses electromagnetic radiation to transfer information between two circuits which have no direct electrical connection.

The term “medium node” means a point of connection, and data storage, collection, and transmission between a central computer, which a user interacts with, and lower points of data storage, collection, and transmission. It can collect infrasound signal data on its own, and also receive pre-collected data from other nodes in order to transfer the entire data set to a higher information processor. Nodes are common circuit elements understood by one of ordinary skill in the art.

The term “wireless networking technology” means a network which uses radio waves to connect devices and allow them to communicate with one another. The wireless networking technology may be Wi-Fi, or a reasonable equivalent.

The term “low node” means a point of data storage, collection, and transmission which does not receive data from any other nodes. It can collect infrasound signal data and communicate this data with higher nodes or with a higher information processor. Nodes are common circuit elements understood by one of ordinary skill in the art.

The term “wireless personal area network (PAN)” means a network which uses radio waves to connect devices within a user's immediate area for transmission of data between the devices. Devices within a PAN do not require a larger wireless network for data to transmit successfully. The wireless personal area network may be Bluetooth® Low Energy (BLE), or another similar technology capable of turning itself on and off between data transmissions.

The term “sleep mode” means a state in which the power supply to power the described technology (ie Wi-Fi, Bluetooth®, sensor, etc.) is temporarily shut off, usually to preserve energy.

The term “datum” may be the status of the infrasound sensor, including the battery life, its remaining storage capacity, its stability, its location, etc., and it may be the infrasound data picked up by the sensor.

The term “external charging source” means a power-transferring device, like a power bank or battery pack, that is used to restore the battery of the infrasound sensor to an increased state of charge. The external charging source may restore the battery wirelessly or via a plug-in. The hierarchal system of data communication through nodes, with the Wi-Fi and Bluetooth® connections temporarily shutting off while not in use, prolongs the battery life of each infrasound sensor. The use of a solar panel reduces the need for external charging sources, as it independently recharges the sensor. The solar panel is not considered an external charging source.

The backing volume equilibrates an inside pressure to an outside pressure in approximately 3 seconds, or about 3 seconds, about 4 seconds, less than 4 seconds, less than 5 seconds, less than 6 seconds, less than 7 seconds, less than 8 seconds, less than 9 seconds, less than 10 seconds, 3-5 seconds, 3-10 seconds, 2-4 seconds, 2-5 seconds, 1-5 seconds.

The simple oscillator has an accuracy of at least 10 ppm, at least 15 ppm, at least 20 ppm, 5-20 ppm, 5-15 ppm, 5-10 ppm, 10-20 ppm, 10-15 ppm, 15-20 ppm, about 10 ppm, approximately 10 ppm. An oscillator with higher accuracy (i.e., 1-5 ppm is more accurate than 10-15 ppm) is typically more expensive and is not considered a simple oscillator in the claims, since the low-cost but high-accuracy time resetting system (via RF signal from a higher-cost and high-accuracy clock) is a critical element to maintaining a low-cost array.

The infrasound sensor has a frequency range of 0.1 Hz-100 Hz, 0.1 Hz-50 Hz, 1 Hz-100 Hz, 50 Hz-100 Hz, 0.1 Hz-10 Hz, 0.1 Hz-75 Hz, 0.1 Hz-99 Hz, 0.5 Hz-100 Hz, 10 Hz-100 Hz, or 0.1 Hz-90 Hz, up to 100 Hz, down to 0.1 Hz.

The RF signal is detectable for at least 1000 feet, at least 900 feet, at least 800 feet, at least 750 feet, at least 600 feet, at least 500 feet, 500-1000 feet, 1000 feet or more, at least 950 feet, at least 975 feet.

The RF signal may be emitted once every 10 seconds, once every 20 seconds, once every 30 seconds, once every 1 minute, once every 100 seconds. The RF signal may be emitted at any frequency required to maintain a maximum of a 1 ms error (drift) of the time of the simple oscillators in the infrasound sensors compared to the GPS clock or expensive and highly accurate oscillator.

The differential GPS sensors are accurate to within 1 cm, about 1 cm, exactly 1 cm, within 2 cm, within 3 cm, within 1-2 cm, within 0.5-1.5 cm, within 1.5 cm, about 2 cm, under 2 cm.

The low-cost sensor can be used in an array with at least 50 infrasound sensors, at least 75 infrasound sensors, at least 100 infrasound sensors, at least 120 infrasound sensors, at least 130, at least 150 infrasound sensors, at least 200 sensors, 100-200 sensors, 50-150 sensors, 50-200 sensors.

With solar panels, the medium nodes last at least a week, at least 7 days, at least 6 days, at least 5 days, up to 9 days, at least 8 days, 7-9 day, 6-9 days without charging.

The infrasound sensor of the present disclosure provides advantages over the prior art in that it is cheaper to manufacture, based on simple and compact mechanics, and can be deployed in a large array while accurately tracking pressure differences over a large area. When used in an array, the infrasound sensors can detect, locate, and track a source of infrasound emission. This is important for improving data collecting, research capabilities, and predictions of incoming dangers (missiles, weather, etc.) that omit infrasound waves. Infrasound is defined as sound frequencies below 20 Hz, and the present infrasound sensors can detect an even wider range of 0.1-100 Hz.

The infrasound sensor measures pressure from air flow very close to the ground, minimizing wind noise. The boundary layer of the earth naturally slows wind near the earth's surface, and placing the inlet pressure port very near (less than 2 cm, about 1 cm, less than 1 cm) to the ground takes advantage of this phenomenon and allows for clean data collection with minimal wind noise. The present infrasound sensor employs a far simpler (and cheaper) method for wind filtering than what is current common practice by simply sampling the pressure very close to the ground.

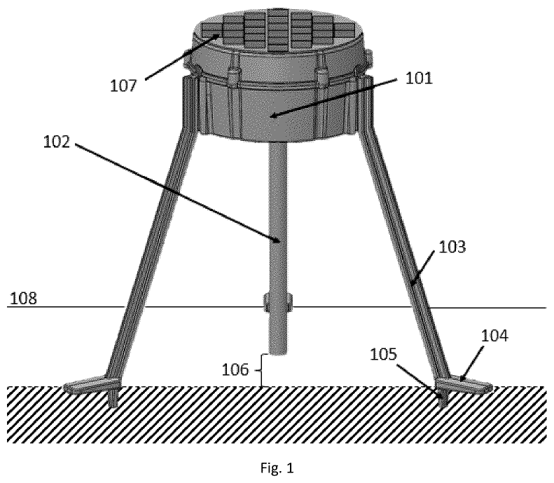

An infrasound sensor as described in the present disclosure is shown in FIG. 1. The main body (101) of the sensor is supported above the ground by 3 legs (103) (the back leg is blocked from view), further comprising feet (104) with stakes (105) that dig into the ground surface (108) to stabilize the infrasound sensor. A pressure port (102) extends down from the main body to sample pressure 1 cm above the ground (106). The infrasound sensor is further equipped with an optional solar panel (107) to prolong the lifetime of the infrasound sensor to at least 7 days.

Fluids flowing past a surface are subject to the “no slip condition” at the surface, where the velocity is zero at the surface. Due to viscosity, this causes the velocity near the surface to be lower than the free stream velocity. The air velocity near a surface, u₂, is related to the air velocity one meter above the ground, u₁, using the following equation where z is the distance from the ground (in meters) and a is an empirically derived factor typically around 0.3.

u₂=u₁z^{a}

This means that placing the port approximately 1 cm from the ground reduces wind velocity by ~75%. Minimizing u₂ by manipulation of z acts to minimize the wind effect on measured samples.

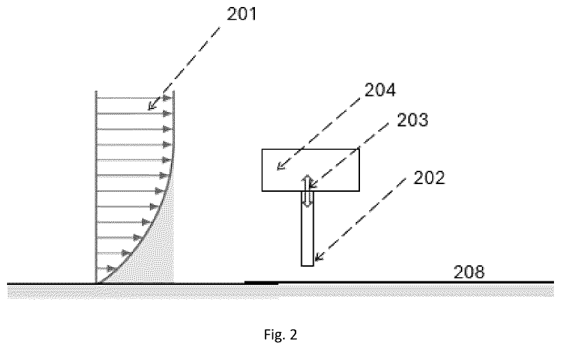

The mechanism of measuring pressure very close to the ground (less than 1 cm) to minimize wind noise is illustrated in FIG. 2. The wind velocity profile (201) illustrates the “no slip condition” due to the earth's boundary layer. Velocity is much higher far away from the ground and very low near the ground, so the pressure port (202) extends to sample pressure where the wind velocity is the lowest, about 1 cm above the ground (208). A differential pressure sensor (203) compares the air pressure outside to the air pressure inside the backing volume (204). The backing volume is an air-tight main body that holds the PCB and has a slow leak through the pressure sensor so the entire infrasound sensor acts as a microbarograph.

In an embodiment of the infrasound sensor described herein, a commercial off the shelf (COTs) mass flow sensor is used to measure pressure (e.g., Sensirion SDP810-125 Pa). The sensing element is essentially a small orifice with a heater. As air flows across the heater, heat is removed. By measuring its own temperature, the heater can determine the air flow rate. Air flow across the orifice is directly related to the pressure difference across the orifice, so it can be inferred from the air flow. This means that the sensing element acts as the slow leak needed in a microbarograph. The sensor body is designed to have the correct volume so that the time constant for the leak to equilibrate the inside pressure to the outside pressure is approximately 3 seconds. At this equilibration rate, a user can see signals of up to 10 seconds (for a lower frequency limit of 0.1 Hz).

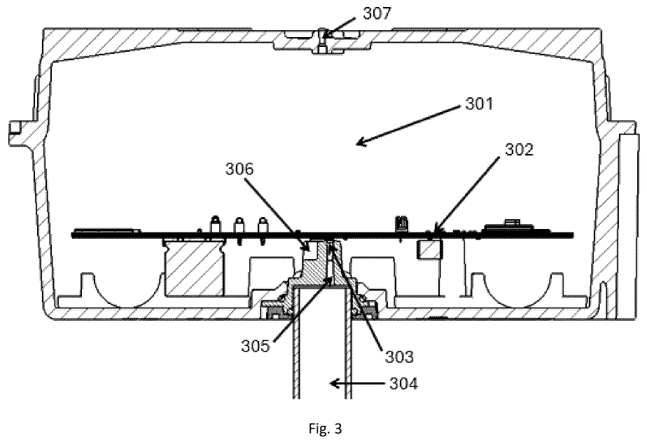

In a preferred embodiment, the sensor is small (5.5 mm×8.5 mm), cheap, highly sensitive (0.08 Pa), and has a fast response (333 samples/second). It has two ports that allow the pressure sensing element to be adapted to function as a microbarograph by attaching one of its two ports to the reference volume (the main body), and the other port to the atmosphere. The connections can be seen in FIG. 3, where the pressure sensor (303) is attached to the PCB (302) and has a reference port (306) connecting the pressure sensor to the housing body backing volume (301) and an outside atmosphere port (305) connecting the pressure sensor to the outside atmosphere via a pressure tube (304) that extends down to less than 1 centimeter off the ground. The infrasound sensor also comprises a press fit hole (307) for push pins that make electrical contact with a solar panel.

The slow leak in the infrasound sensor, with the main body acting as the backing volume, is through the sensing element. Typically, sensing elements in microbarographs are membrane-like elements, where pressure deflects the membrane with no air flowing through it. In a preferred embodiment, the sensing element is a mass flow meter with a small orifice that allows gas to flow through it. The flow meter measures the gas flow rate, which is a function of differential pressure, allowing pressure to be reported.

The body of the infrasound sensor is used as the backing volume needed for a microbarograph. The backing volume dictates the differential pressure, which is the driving force for the gas flow. Preferably, the body of the infrasound sensor is made of an inflexible material, such as a rigid plastic, so the backing volume is not deformed. In an embodiment, the backing volume is 1.8 L and is comprised of all the empty space inside the main body. In alterative configurations, the backing volume may be contained in a separate container, section, or bottle either within a sensor body or in another configuration. Most importantly, the backing volume remains constant during use.

Since the sensor body acts as the backing volume for the present microbarographs (i.e. infrasound sensors), it is important to minimize the number of feedthroughs that could compromise the body's airtightness. In one embodiment, instead of having mechanical switches that are accessible from the outside (that would need to cross the sensor housing), the present sensor implements hall effect sensors as switches. Hall effect sensors measure the local magnetic field. Holding a magnet outside the sensor body, near the hall effect sensor on the other side of the housing, acts to turn the sensor on and off. Separate hall effect sensors are also used to report the status of the sensor (on, connected to the network, etc) through LEDs near a transparent section or through a buzzer. These hall effect sensors allow for manipulation and control of the sensor from the outside of an airtight environment, which preserves accurate measurements from the backing volume.

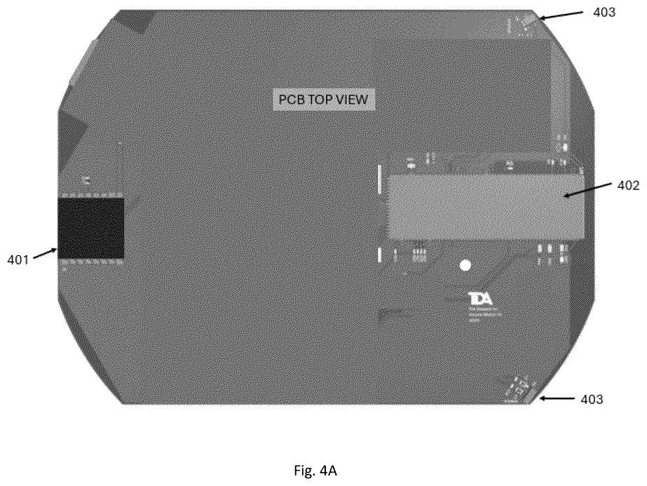

The hall effect sensors and other electronic components of the infrasound sensors are located on a PCB inside the main sensor body. Many configurations are possible, but it is preferred that the PCB comprises a transmitter, a sensing element, pressure ports, and optionally hall sensors and an oscillator. An example of a PCB is shown in FIG. 4A and FIG. 4B. FIG. 4A shows the top view of a PCB, including a transmitter (401) for communicating to a wireless network, a microcontroller unit (MCU) with an internal oscillator (402) and hall sensors (403). FIG. 4B shows the bottom view of the same PCB with a sensing element (404). The sensing element attaches to the commercial sensor, preferably with one port connecting to the inside of the main body, and another port in fluid communication with the outside atmosphere, so the sensing element can measure the pressure differential (of the outside and inside pressures, where the inside pressure also has a slow leak) based on temperature readings from air flow across the sensor. The PCB may be located inside the main body as shown in FIG. 3.

The most expensive component of an infrasound sensor is the detector, in this case the pressure detector. Because of the simplistic nature of the measuring method employed by the disclosed sensors, extremely low-cost detectors can be incorporated into the sensor while maintaining high accuracy. This drives the overall cost down and increases implementation of the present sensor, providing a high advantage for research projects involving large arrays.

The disclosed sensors are designed to be networked into a large array (hierarchical data structure, time keeping, map building, etc.). This means that aside from cost, using these sensors in a large array will be much easier than using other sensors. A typical infrasound array involves a few sensors spread out over many kilometers. An array of the present infrasound sensors could involve hundreds of sensors spread out over just a few hundred meters. The present sensors will allow researchers to investigate how infrasound propagates in the atmosphere with much higher spatial resolution.

Part of the benefit of having a large array of sensors is that a user can investigate how infrasound waves propagate through space over short distances. A method for quickly and accurately building a map of all sensor locations is necessary for this investigation. First, the sensors broadcast their MAC address so that a custom application on a printer receives it and prints out a sticker or label that is scannable, and has data storage and communication capabilities, and may be a QR code®, detailing the unique identifier for that sensor (which is then placed on the sensor housing).

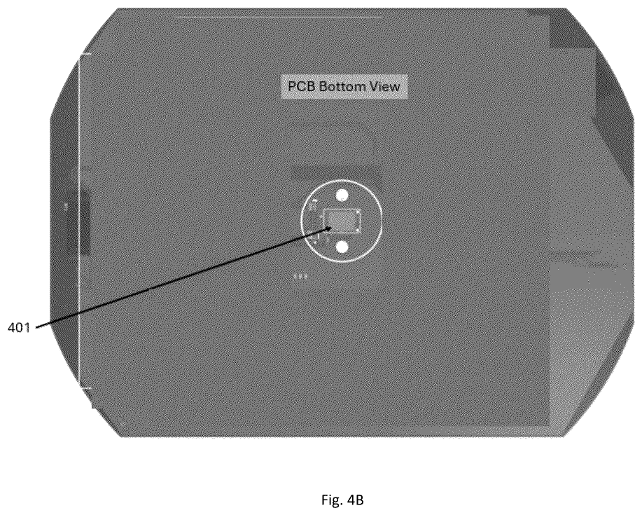

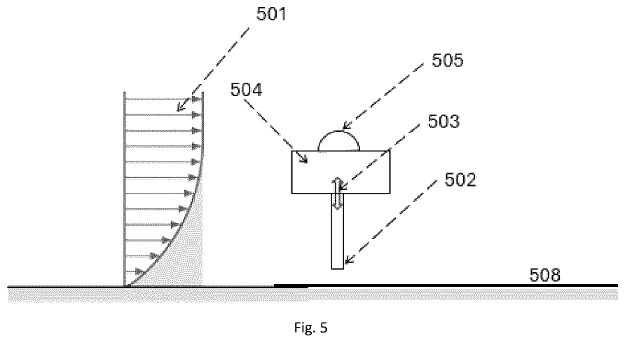

When deploying the sensors, the QR code® is scanned on the sticker on the sensor being deployed. Next, a differential GPS unit with 1 cm accuracy that is built into a “hat” is placed on top of the sensor, as shown in FIG. 5. A single GPS hat (505) may be placed on the infrasound sensor that further comprises a pressure port (502) for measuring air pressure at less than 1 centimeter above the ground )508), where the wind velocity (501) is low. A differential pressure sensor (503) compares the air pressure outside to the air pressure inside the backing volume (504).

The GPS hat communicates wirelessly with the QR code® scanner to relay its GPS coordinates. A button is pressed on the scanner to save the sensor identifying number along with its GPS coordinates into a CSV file. By performing this operation on each sensor during set it up, the result is a CSV file that lists each sensor's unique ID number along with its precise latitude and longitude for an accurate deployment map. A single “hat” with a differential sensor can be used to set up each infrasound sensor. While setting up the array, the QR code® is scanned on the sensor, then the “hat” is placed on the sensor to lock-in the sensor's location and its associated unique ID. Then, the “hat” is removed and taken to the next sensor where the same steps are repeated.

The deployment map is updated with data on which sensors are still collecting data, which might have fallen over, might have low battery, might be overheating, and which ones have stopped collecting data entirely. The deployment map allows a user to monitor the status of a large array of sensors, with their exact GPS locations, in real time.

To properly analyze the infrasound data across the many sensors in the array, there is a need to be able to estimate the arrival time of a signal at each individual sensor. Since sound moves at approximately 334 m/s and sensors could be as close as 1 m apart, all clocks must be synced to within approximately 1 ms. One embodiment of the array of sensors uses low cost oscillators (i.e. clocks) on each sensor with an accuracy of ~10 ppm. With that accuracy, over the course of 1 hour, the clocks accuracy could drift by up to 36 ms (far too much). So, a protocol must be implemented to re-sync all of the clocks every 10 s. A central point has a GPS clock on it (extremely accurate, but expensive clock with consistent updates from the GPS system). This GPS clock sends out a 915 MHz RF signal every 10 s, telling the sensors that receive it to update their clocks to match the GPS clock. Different frequency signals may be used. The RF signal is preferably detectable for >1000 feet. The updating RF signal keeps the whole array synced to within 1 ms.

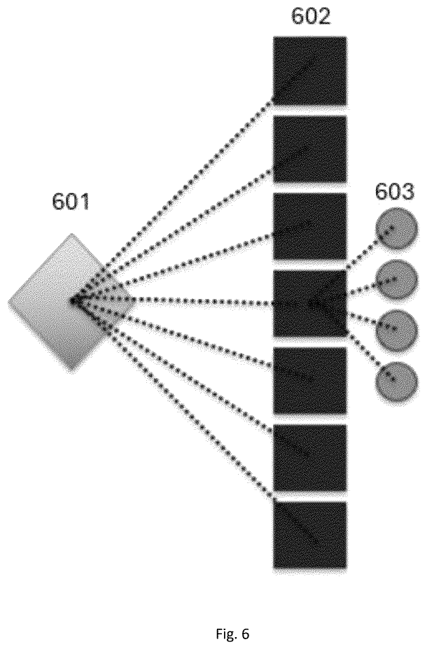

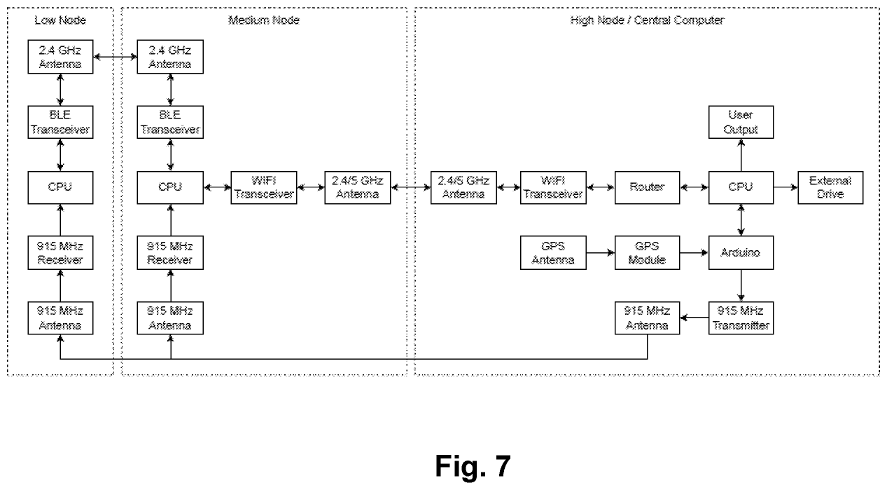

An embodiment of the array of infrasound sensors described herein sets up a system for collecting and transmitting all data from a large number of devices to a single central computer. The central computer connects to a series of “medium nodes” using WiFi. Each medium node connects to up to four “low nodes” via Bluetooth® Low Energy (BLE). FIG. 6 shows the hierarchal system of nodes, with a central computer or high node (601), medium nodes (602), and low nodes (603). This way, the cost of the low nodes is minimized (by eliminating the need for WiFi connectivity, reducing power consumption, and reducing memory needs since they offload data to the medium nodes). Low nodes collect 5 seconds of data and transfer it to medium nodes via BLE. When data is not being transferred, BLE is turned off. Medium nodes also collect data, and they collate that data along with the four low nodes that they are connected to, and send it to the high node (central computer) via a Wi-Fi connection. When data is not being transferred, Wi-Fi is turned off. The data transfer occurs whenever the set of data that the medium node is sending to the central computer is full. When the medium node is connected to four low nodes, this takes about 5 minutes. The high node (central computer) collates all data from the medium and low nodes, has the Wi-Fi antenna, and a GPS antenna that sends out re-syncing pulses (915 MHz transmitter). The flow of data between nodes is shown in FIG. 7.

The hierarchical structure of data collection reduces power consumption, reduces average node cost (since not every sensor needs the hardware necessary to communicate over a long distance to the central computer), and it reduces network congestion (since only ⅕ of the sensors communicate over Wi-Fi to the central computer).

The sensors are designed to consume as little power as possible. Medium nodes last up to 9 days without any recharging, and all sensors have solar panels to recharge during the day. Since BLE and Wi-Fi are the two most power-hungry processes involved in the data collection process, they are turned off most of the time and only turned on when sensors need to communicate to each other. Other processes are also put into sleep mode except when necessary (including the pressure sensor). The hierarchical data structed facilitates low battery consumption in these ways.

### Example

200 low-cost infrasound sensors have been built in-house. The sensor housing is injection molded with posts to hold the printed circuit board PCB) that hosts all of our electronic components in place. The sensor has a custom solar panel that attaches to the top to keep the batteries charged, and legs that snap into place. The legs have feet with small posts. The posts dig slightly into the ground to keep the sensor more stable. A variant could remove the posts or have small holes in the feet so that they can be staked down. There is a tube that extends from the main housing body to sample the pressure very close to the ground (to reduce wind noise).

An O-ring is used to seal the top and bottom layers of the main housing body. On the bottom of the housing, there is a clear rubbery component that holds the tube in place and forms an airtight seal. By using a clear material, a user can see an LED connected to the PCB on the inside which is used as a status signifier (color indicates various states such as on and connected to the network).

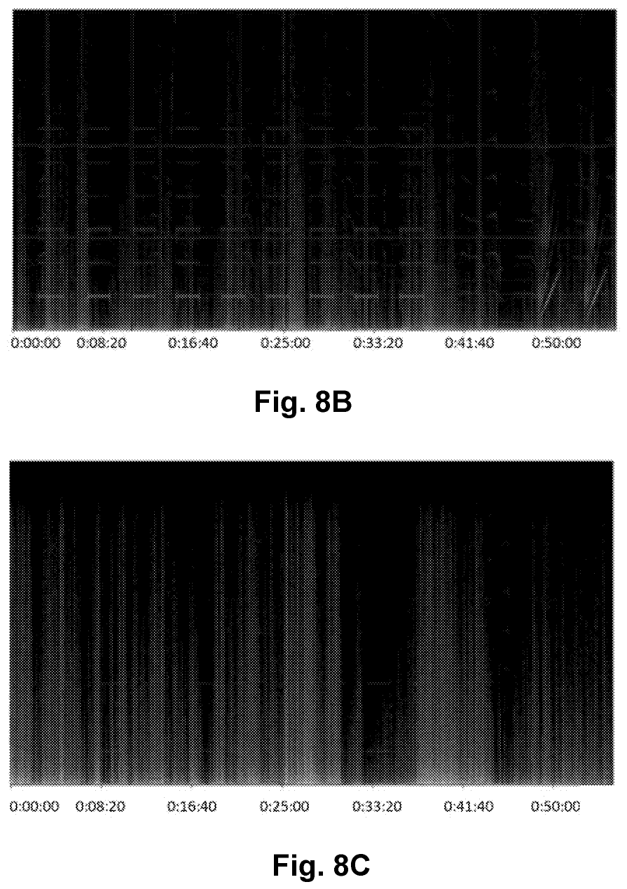

100 sensors were deployed at Kirtland Air Force Base (KAFB) in July 2023 using a rotary subwoofer that can generate signals between 2 Hz-20 Hz. FIG. 8A shows a spectrogram of a single sensor from approximately 10:04 AM-11:04 AM. The x-axis is time, and the Y-axis is frequency. Persistent signals with strong power at a particular frequency will show up as horizontal lines (pink and purple showing high power compared to black, which shows low power). By measuring distances on the Y-axis, we can identify the frequencies of any signals of interest. The 11 Hz cycles and the first few 2-20 Hz sweeps are clearly visible. We can also see overtones of both. For the 11 Hz cycles, we see overtones at 22 Hz, 33 Hz, 44 Hz, 55 Hz, and 66 Hz (with a very faint signal at 77 Hz). There are at least four (possibly more) visible overtones for the sweeps. There are also background signals in the data with a consistent hum at around 30 Hz and another one near 60 Hz.

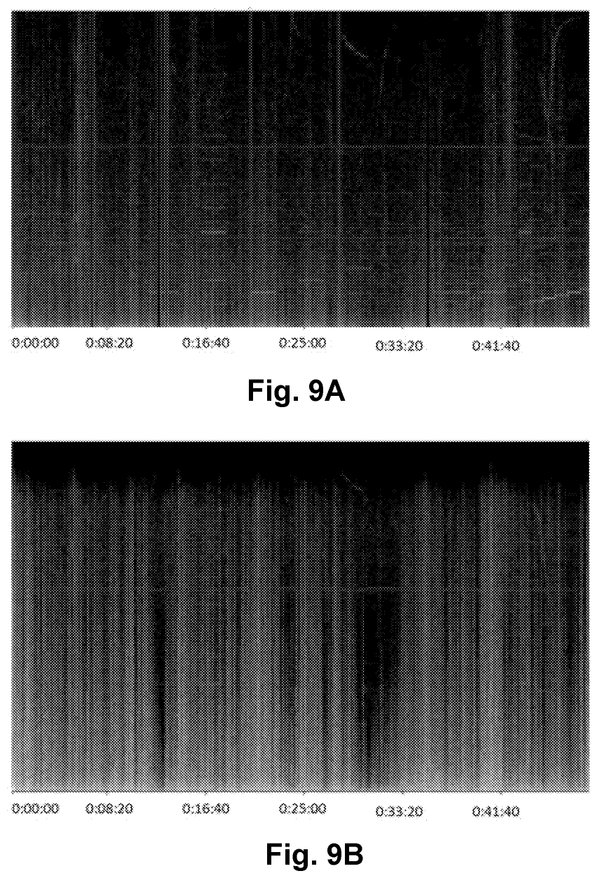

A far more expensive commercially available sensor from Hyperion was deployed in nearly the exact same location at the same time as our sensors. The Hyperion sensor represents the state of the art for infrasound detection technology. Based on the data produced by the Hyperion sensor, it appears that it didn't have any kind of wind filter, since the signals are far harder to see than using the present sensor. FIG. 8B shows the same time frame as FIG. 8A, but with the Hyperion data lined up beneath it (FIG. 8C). The 11 Hz signals as well as the 2 Hz-20 Hz sweeps are both very clear in the data collected using the present sensor. Both are extremely difficult to make out in the data collected by Hyperion's sensor, presumably because they didn't have an effective wind filter attached. FIG. 9 shows similar data from another location at the testing site on both sensors. The signals are extremely difficult to see on Hyperion's sensor (FIG. 9B), but clear and bright pink on the present (FIG. 9A) with no wind noise correction used. What is claimed is . . .

1. An infrasound sensor, the infrasound sensor comprising:
a) a main body, having a bottom side and a top side;
b) a pressure port extending from the bottom side of the main body, having a proximal end connected to the main body and a distal end open to an outside air, further comprising a pressure sensor inside the main body or the pressure port, wherein the pressure sensor can measure an outside air pressure;
c) at least 1 leg extending from the main body;
wherein, when the infrasound sensor is installed on a ground surface with the bottom side facing the ground surface, the distal end of the pressure port is more than 0 centimeters and at most 1 centimeter above the ground surface.

2. The infrasound sensor as in claim 1, wherein the pressure sensor further comprises an orifice for an equalizing leak, wherein the main body is a backing volume for the equalizing leak.

3. The infrasound sensor as in claim 2, wherein the backing volume equilibrates an inside pressure to the outside air in less than 5 seconds.

4. The infrasound sensor as in claim 1, wherein the main body further comprises:
a) a printed circuit board (PCB) within the inside of the main body; and,
b) a transmitter attached to the PCB, wherein the transmitter can wirelessly communicate data from the pressure sensor to an external computer.

5. The infrasound sensor as in claim 4, wherein the main body further comprises at least 1 hall effect sensor attached to the PCB, wherein the at least 1 hall effect sensor is operable to turning the infrasound sensor on and off with a magnet.

6. The infrasound sensor as in claim 1, wherein the main body further comprises an oscillator attached to the PCB, wherein the oscillator has an accuracy of about 10 ppm.

7. The infrasound sensor as in claim 1, wherein the at least 1 leg extending from the main body is at least 3 legs.

8. The infrasound sensor as in claim 1, further comprising a solar panel on the top side of the main body.

9. The infrasound sensor as in claim 1, wherein the infrasound sensor has a frequency detection range of 0.1 Hz-100 Hz.

10. An array of infrasound sensors comprising a multiplicity of infrasound sensors as in claim 1.

11. A method of using an infrasound sensor comprising the steps:
a) providing an infrasound sensor comprising:
i) a main body, having a bottom side, a top side, and inside, and an outside;
ii) a pressure port extending from the bottom side of the main body, having a proximal end connected to the main body and a distal end open to an outside air, further comprising a pressure sensor having a sensing element inside the main body or the pressure port, wherein the pressure sensor can measure an outside air pressure;
iii) at least 1 leg extending from the main body;
wherein, when the infrasound sensor is installed on a ground surface with the bottom side facing the ground surface, the distal end of the pressure port is more than 0 centimeters and at most 1 centimeter above the ground surface;
b) installing the infrasound sensor on the ground surface; and,
c) measuring the pressure.

12. The method as in claim 11, wherein the pressure sensor further comprises an orifice for a small leak, wherein the main body is a backing volume for the small leak, and wherein measuring the pressure comprises the steps:
d) continuously measuring a temperature of the sensing element;
e) determining an air flow rate and a pressure differential between the outside and the inside of the infrasound sensor based on the temperature of the sensing element;
f) equilibrating the pressure differential such that infrasound signals can be resolved, wherein the infrasound signals have a period of up to seconds.

13. The method as in claim 12, wherein the main body further comprising: using at least one hall effect sensor to turn the infrasound sensor on and off, wherein the at least one hall effect sensor is on the inside of the main body of the infrasound sensor and a magnet can activate the at least one hall effect sensor from the outside of the main body of the infrasound sensor, and wherein the method does not comprise opening the main body of the infrasound sensor.

14. A method of using an array of infrasound sensors comprising the steps:
a) providing a multiplicity of infrasound sensors, wherein each infrasound sensor comprises:
i) a main body, having a bottom side, a top side, and inside, and an outside;
ii) a pressure port extending from the bottom side of the main body, having a proximal end connected to the main body and a distal end open to an outside air, further comprising a pressure sensor inside the main body or the pressure port, wherein the pressure sensor can measure an outside air pressure;
iii) at least 1 leg extending from the main body;
wherein, when the infrasound sensor is installed on a ground surface with the bottom side facing the ground surface, the distal end of the pressure port is more than 0 centimeters and at most 1 centimeter above the ground surface;
b) placing the multiplicity of infrasound sensors on the ground surface;
c) measuring the pressure at each infrasound sensor.

15. The method as in claim 14, wherein the multiplicity of infrasound sensors comprises at least 100 infrasound sensors.

16. The method as in claim 14, wherein each infrasound sensor further comprises an oscillator having a less accurate time attached to the PCB, wherein the less accurate time is at least 50% less accurate than a GPS clock, and further comprising the steps:
d) providing a GPS clock having a more accurate time; and,
e) emitting an RF signal from the GPS clock to the simple oscillator on the inside of the main body of each infrasound sensor, wherein the RF signal resets the less accurate time to match the more accurate time;
wherein, emitting an RF signal is repeated such that the difference between the less accurate time and the more accurate time is at most 1 millisecond.

17. The method as in claim 16, wherein the RF signal is detectable for at least 1000 feet.

18. The method as in claim 14, further comprising the steps:
d) creating a deployment map of the multiplicity of infrasound sensors; and,
e) continuously updating the deployment map with the data at each infrasound sensor.

19. The method as in claim 14, wherein each infrasound sensor further comprises a scannable label, wherein the scannable label is capable of data storage and communication, wherein the scannable label has a unique identifying number, and wherein creating a deployment map of the multiplicity of infrasound sensors comprises the steps:
i) providing a differential GPS unit and a differential GPS sensor, wherein the differential GPS sensor is capable of scanning the scannable label and communicating with the differential GPS unit;
ii) scanning the scannable label of an infrasound sensor with the differential GPS sensor;
iii) placing the differential GPS unit on top of the main body of the infrasound sensor;
iv) saving the unique identifying number and its GPS coordinates in a CSV file;
v) repeating steps ii)-iv) for each infrasound sensor; and,
vi) generating a deployment map from the CSV file.

20. The method as in claim 15, further comprising the steps:
d) combining at least one datum from each infrasound sensor at the external computer.

21. The method as in claim 20, wherein combining at least one datum from each infrasound sensor at the external computer comprises the steps:
i) providing a series of low nodes and a series of medium nodes on a wireless network, wherein each medium node has a maximum data capacity;
ii) connecting the external computer to the series of medium nodes on the wireless network, wherein the wireless network is kept in a sleep mode unless data is being transmitted from the series of medium nodes to the external computer or from the series of low nodes to the external computer;
iii) connecting each medium node to at most 4 low nodes on a wireless personal area network, wherein the wireless personal area network is kept in a sleep mode unless data is being transmitted to the medium nodes;
iv) collecting data from the infrasound sensor in the series of low nodes and the series of medium nodes;
v) turning on the wireless personal area network after every 5 seconds of collecting data to transmit data from the series of low nodes to the series of medium nodes;
vi) turning on the wireless network when a medium node reaches its maximum data capacity to transmit data from the medium node to the external computer.

22. The method as in claim 21, wherein each infrasound sensor further comprises a solar panel on the top side of the main body of the infrasound sensor.

23. The method as in claim 22, wherein the solar panel recharges the infrasound sensor, the series of low nodes, and the series of medium nodes such that the infrasound sensor is operable for at least 7 days without requiring an external charging source.
